(19) United States
(12) Patent Application Publication
(10) Pub. No.: US 2026/0371998 A1
(43) Pub. Date: Nov. 19, 2026

(54) OBSERVATION APPARATUS, OBSERVATION METHOD, AND METHOD FOR MANUFACTURING SEMICONDUCTOR DEVICE

(71) Applicant: JSW Aktina System Co., Ltd., Yokohama-shi, Kanagawa (JP)

(72) Inventors: Yoshihiro YAMAGUCHI, Yokohama-shi, Kanagawa (JP); Daisuke ITO, Yokohama-shi, Kanagawa (JP)

(73) Assignee: JSW Aktina System Co., Ltd., Yokohama-shi, Kanagawa (JP)

(21) Appl. No.: 19/132,599

(22) PCT Filed: Dec. 20, 2022
(86) PCT No.: PCT/JP2022/046920

§ 371 Date: May 23, 2025

(51) Int. Cl. H10P 72/00; B65G 49/06; H10P 72/30; H10P 72/76; H10P 74/20

(52) U.S. Cl. CPC H10P 72/0616; B65G 49/06; H10P 72/36; H10P 72/7602; H10P 74/203

(57) ABSTRACT

An observation apparatus (100) according to an embodiment of the present disclosure includes: a mechanism configured to levitate or support a substrate (16) so that a space is formed directly below the substrate; a conveyance mechanism configured to convey the substrate levitated or supported above the mechanism in a conveyance direction; an observation unit (50) including a photodetector (52) configured to detect light from the substrate (16), and an optical system (51) configured to guide the light from the substrate (16) to the photodetector (52); and a moving mechanism (55) configured to move the observation unit (50) in a direction inclined from the conveyance direction in a plan view.

### TECHNICAL FIELD

The present invention relates to an observation apparatus, an observation method, and a method for manufacturing a semiconductor device.

### BACKGROUND ART

Patent Literature 1 discloses a laser annealing apparatus using an excimer laser. In Patent Literature 1, a conveyance unit conveys a substrate in a state where a levitation unit levitates the substrate.

Then, during the conveyance of the substrate, the substrate is irradiated with laser light in such a manner that its irradiated area has a linear shape. Further, the laser irradiation apparatus includes a line sensor disposed on the substrate. The line sensor takes an image of the substrate during the conveyance thereof.

### CITATION LIST

### Patent Literature

Patent Literature 1: Japanese Unexamined Patent Application Publication No. 2018-64048

### SUMMARY OF INVENTION

### Technical Problem

In such an apparatus, it is desired to be able to properly observe the substrate.

Other problems and novel features will be apparent from the descriptions in this specification and the accompanying drawings.

### Solution to Problem

According to an embodiment, an observation apparatus includes: a mechanism configured to levitate or support a substrate so that a space is formed directly below the substrate; a conveyance mechanism configured to convey the substrate levitated or supported above the mechanism in a conveyance direction; an observation unit including a photodetector configured to detect light from the substrate, and an optical system configured to guide the light from the substrate to the photodetector; and a moving mechanism configured to move the observation unit in a direction inclined from the conveyance direction in a plan view so as to change an observation position on the substrate.

According to an embodiment, an observation method is an observation method performed in an observation apparatus, the observation apparatus including: a mechanism configured to levitate or support a substrate so that a space is formed directly below the substrate; and an observation unit including a photodetector configured to detect light from the substrate, and an optical system configured to guide the light from the substrate to the photodetector, the observation method including: (A1) a step in which a conveyance mechanism conveys the substrate in a conveyance direction; (A2) a step of observing the substrate conveyed by the conveyance mechanism by using the observation unit; and (A3) a step of observing the substrate while changing an observation position on the substrate by moving the observation unit in a direction inclined from the conveyance direction in a plan view.

According to an embodiment, a method for manufacturing a semiconductor device includes: (S1) a step of levitating or supporting a substrate by using a mechanism so that a space is formed directly below the substrate; (S2) a step of conveying the substrate levitated or supported above the mechanism in a conveyance direction by using a conveyance mechanism; (S3) a step of observing the substrate by using an observation unit including a photodetector configured to detect light from the substrate, and an optical system configured to guide the light from the substrate to the photodetector; and (S4) a step of moving the observation unit in a direction inclined from the conveyance direction in a plan view by using a moving mechanism so as to change an observation position on the substrate.

### Advantageous Effects of Invention

According to the above-described embodiments, it is possible to provide an observation apparatus and an observation method capable of properly observing a substrate, and a method for manufacturing a semiconductor device in which a substrate can be properly observed.

### BRIEF DESCRIPTION OF DRAWINGS

FIG. 1 is an XY-plane view schematically showing an observation apparatus according to a first embodiment;

FIG. 2 is an XZ-plane view schematically showing the observation apparatus according to the first embodiment;

FIG. 3 is a YZ-plane view schematically showing the observation apparatus according to the first embodiment;

FIG. 4 is an enlarged view showing a configuration of an observation unit;

FIG. 5 is an XY-plane view schematically showing an observation apparatus according to a second embodiment;

FIG. 6 is an XZ-plane view schematically showing the observation apparatus according to the second embodiment;

FIG. 7 is an XY-plane view schematically showing the observation apparatus according to the third embodiment;

FIG. 8 is an XZ-plane view schematically showing an observation apparatus according to a third embodiment;

FIG. 9 is an XY-plane view schematically showing an observation apparatus according to a fourth embodiment;

FIG. 10 is an XZ-plane view schematically showing the observation apparatus according to the fourth embodiment;

FIG. 11 is an enlarged XY-plane view showing a configuration of an observation unit and a sucking unit;

FIG. 12 is an enlarged XZ-plane view showing a configuration of the observation unit when the sucking unit adsorbs the substrate;

FIG. 13 is an enlarged XZ-plane view showing a configuration of the observation unit when the sucking unit releases the sucking fixation of the substrate;

FIG. 14 is an XZ-plane view schematically showing an observation apparatus according to a fifth embodiment;

FIG. 15 is an XY-plane view schematically showing a configuration of a precision levitation unit;

FIG. 16 is an XZ-plane view schematically showing a configuration of the precision levitation unit;

FIG. 17 is an XY-plane view schematically showing an observation apparatus according to a sixth embodiment;

FIG. 18 is an XZ-plane view schematically showing the observation apparatus according to the sixth embodiment;

FIG. 19 is an XY-plane view schematically showing an observation apparatus according to a seventh embodiment;

FIG. 20 is an XZ-plane view schematically showing the observation apparatus according to the seventh embodiment;

FIG. 21 is an XY-plane view schematically showing an observation apparatus according to an eighth embodiment;

FIG. 22 is an XZ-plane view schematically showing the observation apparatus according to the eighth embodiment;

FIG. 23 is a YZ-plane view schematically showing the observation apparatus according to the eighth embodiment;

FIG. 24 is an XY-plane view schematically showing a configuration of the observation apparatus according to the eighth embodiment when the moving direction thereof is changed;

FIG. 25 is an XY-plane view schematically showing an observation apparatus according to a ninth embodiment;

FIG. 26 is an XZ-plane view schematically showing the observation apparatus according to the ninth embodiment;

FIG. 27 is a YZ-plane view schematically showing the observation apparatus according to the ninth embodiment;

FIG. 28 is an XY-plane view schematically showing an observation apparatus according to a tenth embodiment;

FIG. 29 is an XZ-plane view schematically showing the observation apparatus according to the tenth embodiment;

FIG. 30 is a schematic view showing a configuration of a laser irradiation apparatus including an observation apparatus;

FIG. 31 is a simplified cross-sectional view showing a structure of an organic EL display;

FIG. 32 is a cross-sectional view showing a step in a method for manufacturing a semiconductor device according to an embodiment of the present disclosure; and

FIG. 33 is a cross-sectional view showing a step in the method for manufacturing a semiconductor device according to the embodiment of the present disclosure.

### DESCRIPTION OF EMBODIMENTS

An observation apparatus according to an embodiment of the present disclosure is an observation apparatus for observing a substrate from the rear surface side thereof. The substrate is, for example, a glass substrate for an organic EL (Electro-Luminescent) display.

Various patterns such as a metal wiring layer, a transparent electrode layer, a semiconductor layer, a light emitting layer, and a color filter layer are formed over the glass substrate. That is, a lot of layers having respective patterns are formed over the glass substrate.

Note that in the drawings described below, an XYZ three-dimensional orthogonal coordinate system is shown as appropriate for simplifying the description. The Z direction is a vertical up/down direction and is perpendicular to the main surface of the substrate. The XY plane is a plane parallel to the main surface of the substrate. The XY directions are parallel to the edges of the rectangular substrate. Further, the X direction is the conveyance direction of the substrate. The Y direction is perpendicular to the X and Z directions.

### First Embodiment

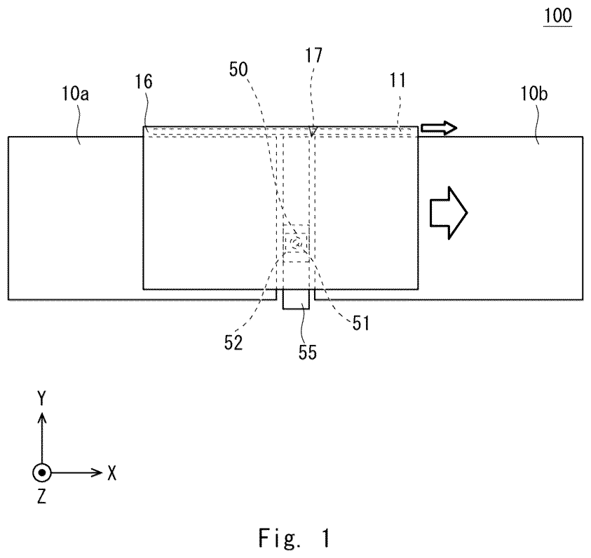

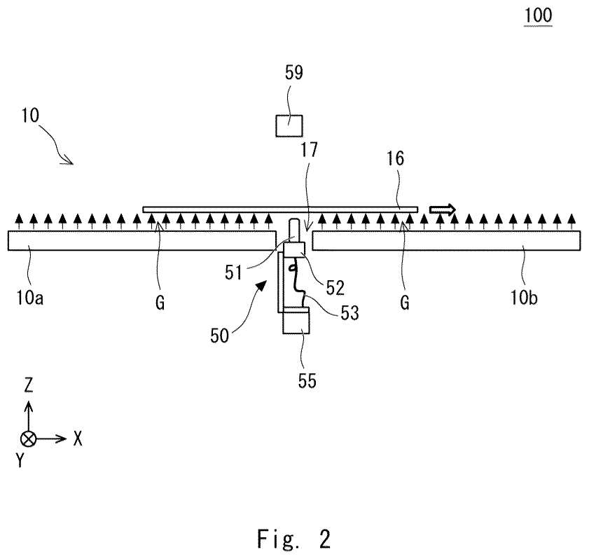

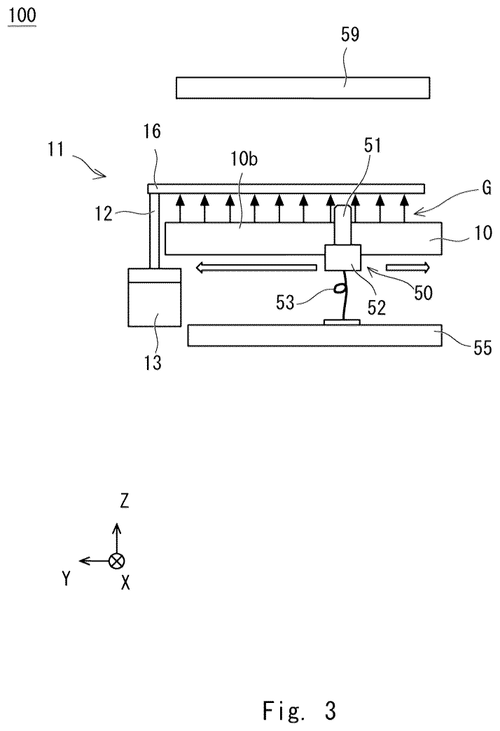

A configuration of an observation apparatus according to a first embodiment will be described with reference to FIGS. 1 to 3. FIG. 1 is a plan view (XY plane view) schematically showing the configuration of the observation apparatus 100. FIG. 2 is a side view (XZ plane view) schematically showing a configuration of a laser irradiation apparatus 1. FIG. 3 is a side view (YZ plane view) schematically showing the configuration of the laser irradiation apparatus 1.

The observation apparatus 100 includes a levitation unit 10, a conveyance mechanism 11, and an observation unit 50. As shown in FIG. 2, the levitation unit 10 is configured to eject gas from its surface. The levitation unit 10 levitates a substrate 16 over its upper surface. The gas ejected from the surface of the levitation unit 10 is blown onto the lower surface of the substrate 16, so that the substrate 16 levitates. For example, when the substrate 16 is conveyed, the levitation unit 10 adjusts the levitating height of the substrate 16 so that the substrate 16 does not collide with any of other mechanisms (not shown) disposed above the substrate 16.

The levitation unit 10 ejects gas onto the substrate 16 so that the substrate 16 is not in contact with the levitation unit 10. Therefore, a space G is formed directly below the substrate 16. The space G is a minute air gap formed by gas ejected from the levitation unit 10. That is, the space G is a gap between the upper surface of the levitation unit 10 and the lower surface of the substrate 16. Note that the gas ejected from the levitation unit 10 may be air, nitrogen, or dried gas.

The levitation unit 10 serves as a mechanism for levitating the substrate 16 so that a space G is formed directly below the substrate 16. The levitation unit 10 includes a plurality of levitation unit cells 10a and 10b. The levitation unit cell 10b is disposed on the +X side of the levitation unit cell 10a. The levitation unit cells 10a and 10b are arranged with a gap 17 therebetween. Each of the levitation unit cells 10a and 10b ejects gas. The observation unit 50 is disposed between the levitation unit cells 10a and 10b. The observation unit 50 will be described later.

Each of the levitation unit cells 10a and 10b may be formed of a porous element such as ceramic. As the porous element, porous carbon, porous alumina ceramic, porous SiC ceramic, or the like may be used. Each of the levitation unit cells 10a and 10b may be formed of a metal material with a plurality of gas ejecting holes formed therein.

The conveyance mechanism 11 is disposed on the +Y side of the levitation unit 10. The conveyance mechanism 11 conveys the substrate 16, which is levitating, in the conveyance direction. As shown in FIG. 3, the conveyance mechanism 11 includes a holding mechanism 12 for vacuum-sucking the end of the substrate 16. The holding mechanism 12 sucks and holds the end of the substrate 16 on the +Y side.

For example, the holding mechanism 12 may be formed by using a vacuum-sucking mechanism. The vacuum-sucking mechanism is formed of a metal material such as an aluminum alloy. Alternatively, the holding mechanism 12 may be formed of a resin-based material such as a PEEK (PolyEtherEtherKetone) material. A sucking groove(s), a sucking hole(s), or the like is formed in the upper surface of the holding mechanism 12. The holding mechanism 12 may be formed of a porous element.

The holding mechanism 12 is connected to a driving mechanism 13. The driving mechanism 13 moves the holding mechanism 12 in the X direction. The driving mechanism 13 includes an actuator such as an air cylinder or a motor. For example, the driving mechanism 13 includes a guide mechanism extending along the X direction. Further, the driving mechanism 13 slides the holding mechanism 12 along the X direction. In this way, the conveyance mechanism 11 can convey the substrate 16 in the X direction. Further, the driving mechanism 13 may include a raising/lowering mechanism for raising and lowering the holding mechanism 12 in the Z direction (up/down direction).

In the X direction, the observation unit 50 is disposed in the gap 17 between the levitation unit cells 10a and 10b. The observation unit 50 includes a photodetector 52 and an optical system 51. For the photodetector 52, a CCD (Charge-Coupled Device) camera, a CMOS (Complementary Metal-Oxide-Semiconductor) image sensor, or a photodiode array may be used. The photodetector 52 is a camera in which pixels are arranged in the X direction and in the Y directions.

The optical system 51 guides light from the substrate 16 to the photodetector 52. In this way, the photodetector 52 can take an image of the substrate 16. For example, the optical system 51 includes an objective lens or the like which forms a magnified image of the substrate 16. For example, the observation unit 50 can take a magnified image of the substrate 16 magnified by a factor of 50 to 100. The optical system 51 may include other optical elements such as a lens, a beam splitter, and a filter.

A cable 53 for supplying electric power and for receiving and outputting signals is connected to the photodetector 52. Image data taken by the photodetector 52 is stored in a memory or the like. Alternatively, an image may be displayed on an external monitor.

Further, the observation unit 50 is connected to a moving mechanism 55. The moving mechanism 55 moves the observation unit 50 in the Y direction. Note that the photodetector 52 moves together with the optical system 51. In XY plane view, the position of the observation unit 50 relative to the substrate 16 changes. The observation apparatus 100 can change the observation position on the substrate 16 (i.e., an area on the substrate 16 which the observation apparatus 100 observes).

The moving mechanism 55 changes the position of the observation unit 50 in the Y direction. Further, the conveyance mechanism 11 conveys the substrate 16 in the X direction. In this way, the observation unit 50 can take an image of an arbitrary position (i.e., an arbitrary area) on the substrate 16. The observation apparatus 100 can take images of a plurality of observation positions on the substrate 16. Since the relative position of the observation unit 50 relative to the substrate 16 changes in the X and Y directions, the observation apparatus 100 can use a desired position on the substrate 16 as the observation position thereon. Note that the moving direction of the moving mechanism 55 and the conveyance direction of the conveyance mechanism 11 in the plan view are not limited to the directions shown in the drawings. The moving direction of the moving mechanism 55 and the conveyance direction of the conveyance mechanism 11 in the plan view are not limited to directions perpendicular to each other. That is, it is sufficient if these directions are inclined from each other.

Note that in FIGS. 2 and 3, an illumination light source 59 is disposed above the substrate 16. The illumination light source 59 generates illumination light for illuminating the substrate 16. The observation unit 50 receives light from the area illuminated by the illumination light source 59. Note that a lens or the like for concentrating the illumination light from the illumination light source 59 on the substrate 16 may be provided.

Note that the position of the illumination light source 59 is not limited to the position above the substrate 16. For example, the illumination light source 59 may be disposed so that its optical axis coincides with the optical axis of the optical system 51. Further, the illumination light source 59 may be ring illumination arranged outside the lens. Alternatively, a room light or the like may be used as the illumination light source 59. The illumination light source 59 may generate illumination light in such a manner that its irradiated area has a linear shape along the Y direction. Alternatively, the illumination light source 59 may be moved along the Y direction together with the observation unit 50 as described later.

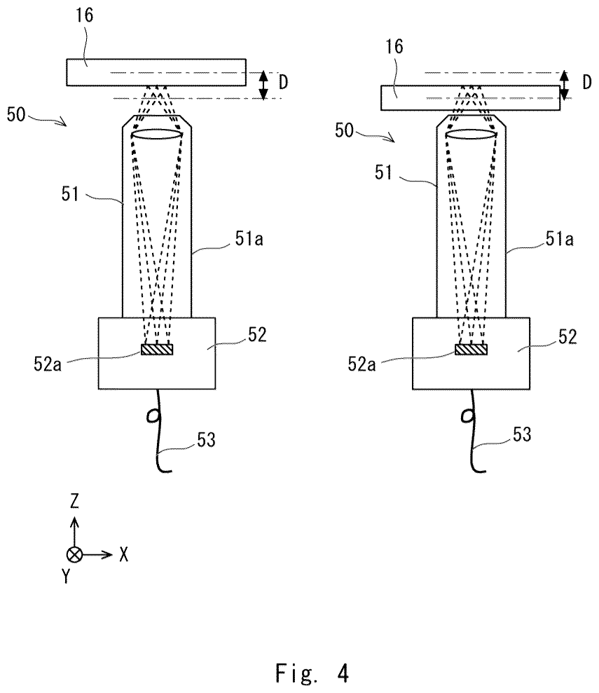

FIG. 4 is an enlarged view showing the configuration of the observation unit 50. In FIG. 4, a lens barrel of an objective lens 51a is shown as the optical system 51. The optical system 51 is fixed to the photodetector 52. By the light refracted by the optical system 51, an image is formed on an imaging device 52a of the photodetector 52. The imaging device 52a is a two-dimensional array photodetector having a plurality of pixels arranged in the X direction and in the Y directions. Note that although only one lens is shown in the lens barrel of the objective lens 51a in FIG. 4, a plurality of lenses may be provided in the lens barrel.

For example, the optical axis of the objective lens 51a is parallel to the Z direction. Therefore, the position on the substrate 16 (i.e., the area on the lower surface of the substrate 16) directly above the photodetector 52 becomes the observation position on the substrate 16. It should be noted that when the height of the substrate 16 is changed by an amount equal to or larger than the focal depth D of the objective lens 51a, the image of the substrate 16 is blurred. In this embodiment, since the levitation unit 10 is used, the height of the substrate 16 can be controlled with high precision. By using the observation apparatus 100 according to this embodiment, the substrate 16 can be properly observed.

In particular, the levitation unit 10 is (i.e., the levitation unit cells 10a and 10b are) disposed on both sides of the substrate 16 in the X direction. That is, the levitation unit cell 10a is disposed on the −X side of the substrate 16, and the levitation unit cell 10b is disposed on the +X side of the substrate 16. In this way, fluctuations in the height of the substrate 16 can be suppressed, so that the image can be prevented from being blurred. By using the observation apparatus 100 according to this embodiment, it is possible to properly take an image of the substrate 16.

Further, as shown in FIGS. 2 and 3, a part of the optical system 51 is disposed above the levitating surface of the levitation unit 10.

Specifically, the upper end of the objective lens 51a is disposed above the levitating surface of the levitation unit 10. In this way, an objective lens 51a having a short working distance can be used in the optical system 51. Since an objective lens having a large numerical aperture can be used, the observation unit 50 can take a high-resolution image.

The observation unit 50 is disposed below the substrate 16. The substrate 16 can be observed from the rear surface side thereof. That is, it is possible to take an image of the pattern formed on the substrate 16 through a transparent substrate. Even when an opaque metal layer or the like is formed on the upper surface side of the substrate 16, it is possible to take an image of a pattern formed on a layer of the substrate 16 located below the opaque layer thereof. In this way, the substrate can be inspected with high precision.

### Second Embodiment

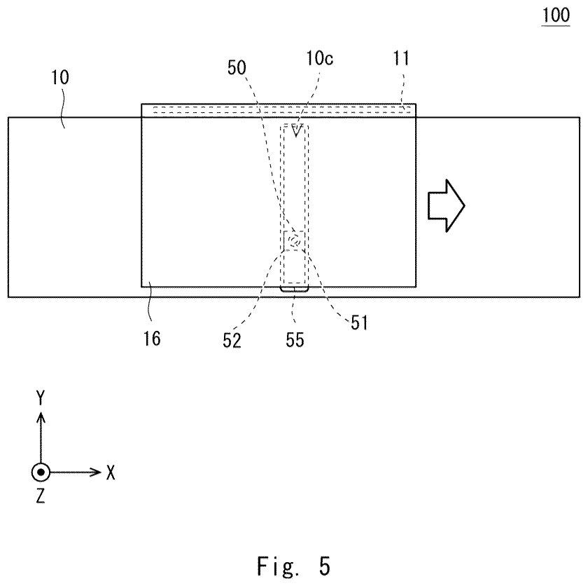

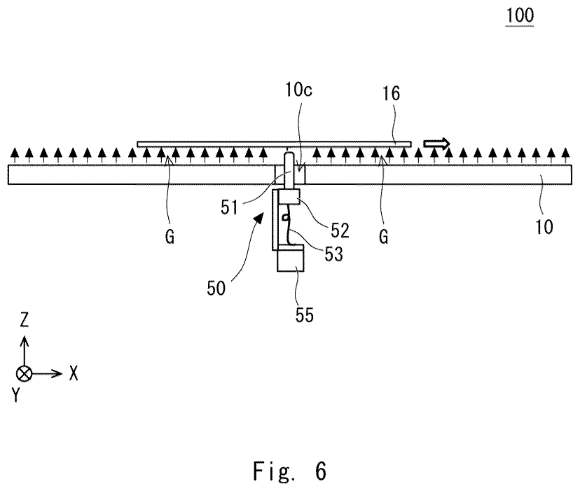

An observation apparatus 100 according to a second embodiment will be described with reference to FIGS. 5 and 6. FIG. 5 is an XY plane view showing the configuration of the observation apparatus 100. FIG. 6 is an XZ plane view showing the configuration of the observation apparatus 100. The configuration of the levitation unit 10 in the second embodiment is different from that in the first embodiment. The rest of the configuration other than the levitation unit 10 is similar to that of the first embodiment, and therefore

In this example, the levitation unit 10 is not separated into two levitation unit cells 10a and 10b. That is, the levitation unit 10 is integrally formed as one component. Further, an opening 10c for disposing the observation unit 50 is formed in the levitation unit 10. The opening 10c is formed along the Y direction. That is, the opening 10c has a rectangular shape of which the long-side direction is parallel to the Y direction and the short-side direction is parallel to the X direction. The observation unit 50 moves in the Y direction inside the opening 10c.

Even in the above-described configuration, the substrate 16 can be properly observed. In the X direction, the levitation unit 10 is (i.e., parts of the levitation unit 10 are) disposed on both sides of the substrate 16. In this way, fluctuations in the height of the substrate 16 can be suppressed. By using the observation apparatus 100 according to this embodiment, it is possible to properly take an image of the substrate 16.

Note that the space for disposing the observation unit 50 is not limited to the opening 10c, and instead may be a recess or the like. That is, a groove extending along the Y direction may be formed in the upper surface of the levitation unit 10. Further, the moving mechanism 55 may move the observation unit 50 along the groove.

### Third Embodiment

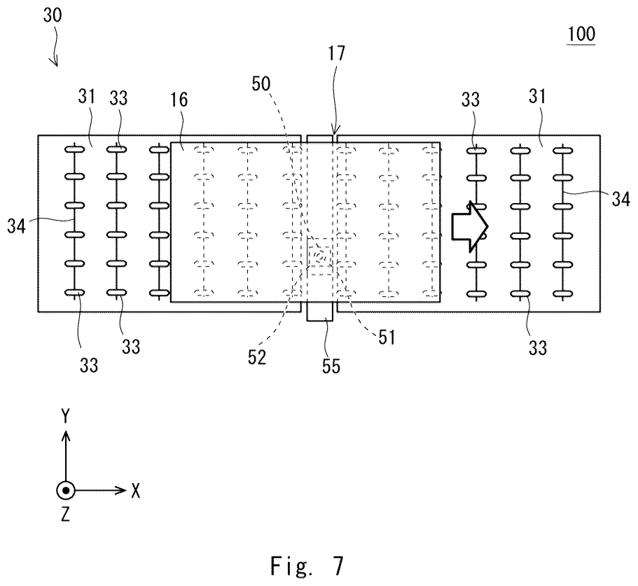

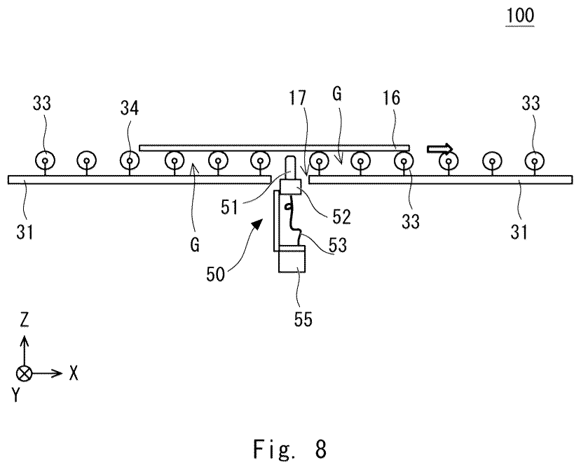

An observation apparatus 100 according to a third embodiment will be described with reference to FIGS. 7 and 8. FIG. 7 is an XY plane view showing the configuration of the observation apparatus 100. FIG. 8 is an XZ plane view showing the configuration of the observation apparatus 100. In the third embodiment, a support unit 30 is provided in place of the levitation unit 10 of the first and second embodiments. Note that the rest of the configuration other than the support unit 30 is similar to that of the first embodiment, and therefore description thereof is omitted.

The support unit 30 includes a base stage 31 and a plurality of conveyance rollers 33. The base stage 31 is disposed directly below the substrate 16. The plurality of conveyance rollers 33 are disposed in the base stage 31. In an XY plane view, the plurality of conveyance rollers 33 are arranged in an array. The plurality of conveyance rollers 33 are rotatably attached to the base stage 31. The rotation axes 34 of the conveyance rollers 33 are parallel to the Y axis.

The conveyance rollers 33 are disposed above the base stage 31. Therefore, the conveyance rollers 33 come into contact with the lower surface of the substrate 16. The heights of the plurality of conveyance rollers 33 are equal to each other. As the conveyance rollers 33 rotate, the substrate 16 is conveyed in the X direction.

By the above-described configuration, a space G is formed directly below the substrate 16. The support unit 30 is a mechanism for supporting the substrate 16 so that the space G is formed directly below the substrate 16. An objective lens of the optical system 51 is disposed in the space G formed directly below the substrate 16. Therefore, similarly to the first and second embodiments, the observation unit 50 can properly take an image of the substrate 16. As a result, the substrate 16 can be properly observed.

### Fourth Embodiment

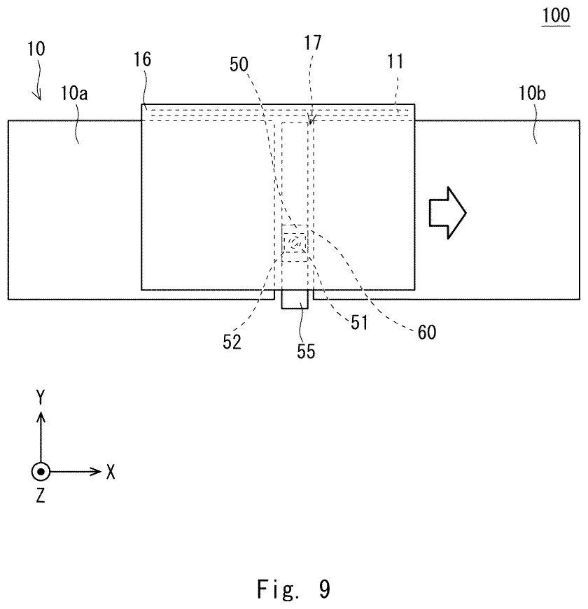

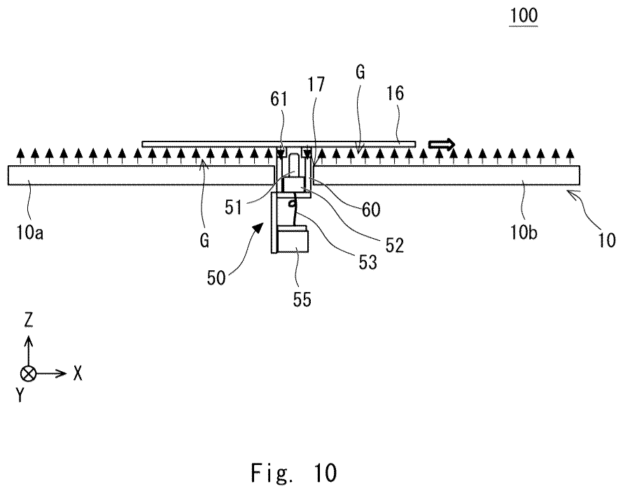

An observation apparatus according to a fourth embodiment will be described with reference to FIGS. 9 and 10. FIG. 9 is an XY plane view showing the configuration of the observation apparatus 100. FIG. 10 is an XZ plane view showing the configuration of the observation apparatus 100. In this embodiment, a sucking unit 60 is provided around the observation unit 50. The rest of the configuration other than the sucking unit 60 is similar to that of the first embodiment, and therefore description thereof is omitted.

The sucking unit 60 vacuum-sucks and fixes the substrate 16. The observation unit 50 is housed inside the sucking unit 60. The moving mechanism 55 moves the observation unit 50 in the Y direction together with the sucking unit 60.

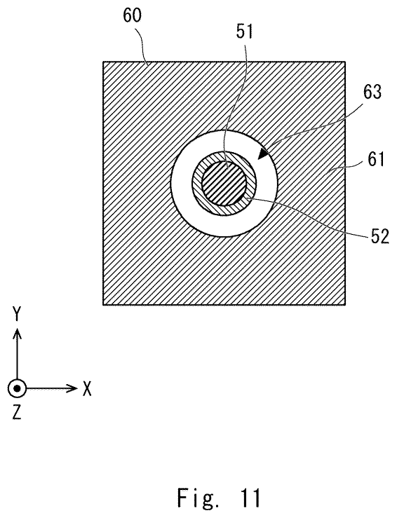

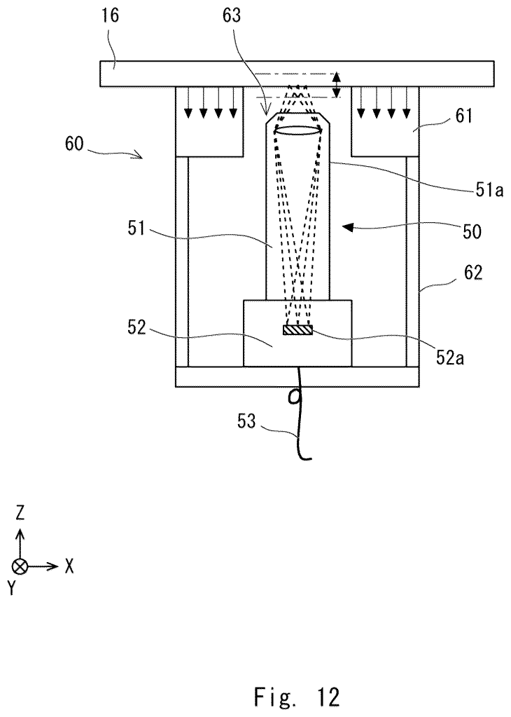

The configuration of the sucking unit 60 will be described with reference to FIGS. 11 and 12. FIG. 11 is a plan view showing the configuration of the sucking unit 60. FIG. 12 is an XZ cross-sectional view showing the configuration of the sucking unit 60.

The sucking unit 60 includes a sucking part 61, a housing part 62, and a window part 63. The housing part 62 is a case (housing) for housing the observation unit 50. The photodetector 52 and the optical system 51 are fixed to the housing part 62. A cable 53 is pulled out to the outside of the housing part 62. The moving mechanism 55 moves the housing part 62 along the Y direction. In this way, since the observation unit 50 moves, the observation position on the substrate 16 can be changed in the Y direction.

Further, the sucking part 61 is provided above the housing part 62. The sucking part 61 can suck and hold the substrate 16 by sucking gas from its upper surface. The upper surface of the sucking part 61 serves as a sucking surface. The upper end of the objective lens 51a is located below the sucking surface of the sucking part 61.

The sucking part 61 includes the circular window part 63. Light from the substrate 16 enters the optical system 51 through the window part 63. The window part 63 may be a space, or a transparent member such as glass may be disposed therein. In this way, the sucking unit 60 can suck and hold the entire circumference of the observation area on the substrate 16. The sucking unit 60 can suck and hold the area surrounding the observation area on the substrate 16.

The sucking unit 60 fixes the substrate 16 by vacuum-sucking. In this way, fluctuations in the height of the substrate 16 can be suppressed more effectively. That is, it is possible to make the distance from the objective lens 51a to the lower surface of the substrate 16 constant, and thereby to observe the substrate 16 more properly. Therefore, it is possible to observe the substrate 16 in a stable manner.

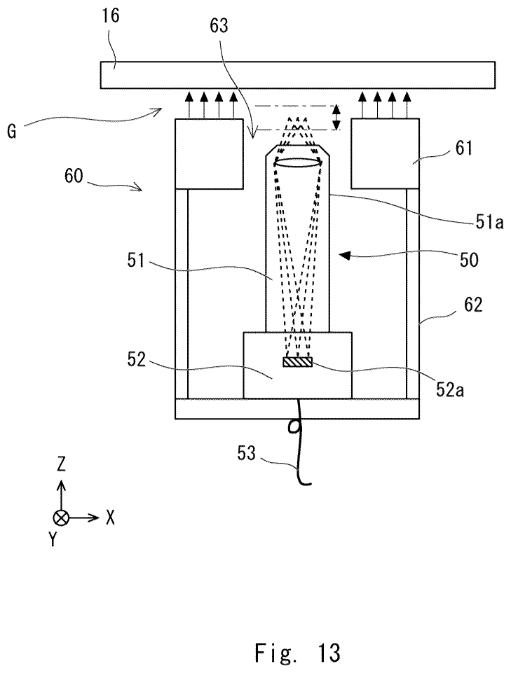

The sucking unit 60 sucks and holds the substrate 16 when the substrate 16 is observed. Further, when the substrate 16 is conveyed, the sucking unit 60 releases the sucking and holding of the substrate 16. For example, as shown in FIG. 13, gas may be ejected from the sucking part 61. In this way, a space G is formed between the substrate 16 and the sucking part 61. That is, since the substrate 16 is levitated by air, the conveyance mechanism 11 can convey the substrate 16.

### Fifth Embodiment

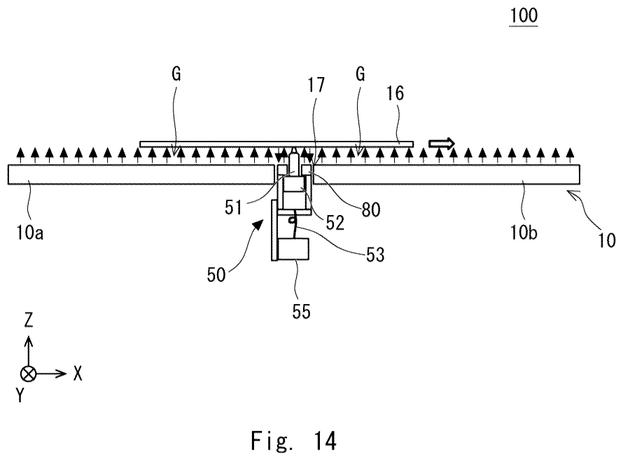

An observation apparatus according to a fifth embodiment will be described with reference to FIG. 14. FIG. 14 is an XZ plane view showing the configuration of the observation apparatus 100. In this embodiment, a precision levitation unit 80 is provided around the observation unit 50. In other words, the sucking unit in the fourth embodiment is replaced by the precision levitation unit 80. The rest of the configuration other than the precision levitation unit 80 is similar to that of the first embodiment, and therefore description thereof is omitted.

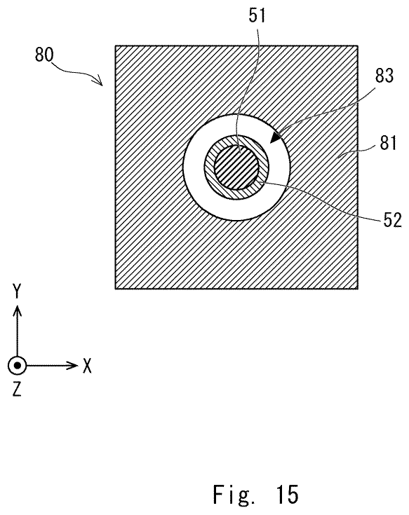

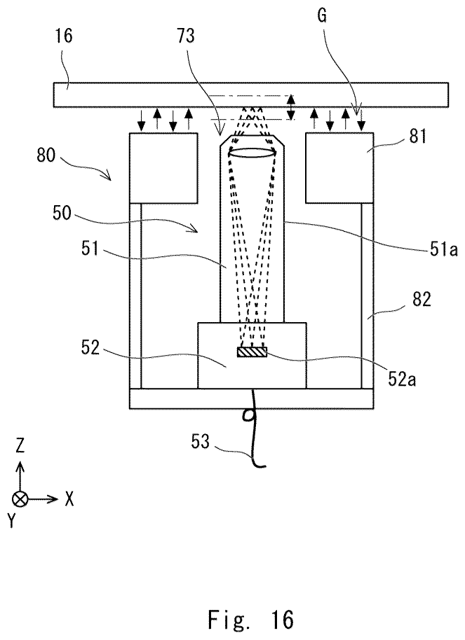

The configuration of the precision levitation unit 80 will be described with reference to FIGS. 15 and 16. FIG. 15 is a plan view showing the configuration of the precision levitation unit 80. FIG. 16 is an XZ cross-sectional view showing the configuration of the precision levitation unit 80.

The precision levitation unit 80 includes a housing part 82 and a sucking/ejecting part 81. The housing part 82 is a case (housing) for housing the observation unit 50. The photodetector 52 and the objective lens 51a are fixed to the housing part 82. The cable 53 is pulled out to the outside of the housing part 82. The moving mechanism 55 moves the housing part 82 along the Y direction. In this way, since the observation unit 50 moves, the observation position on the substrate 16 can be changed in the Y direction.

The sucking/ejecting part 81 is disposed above the housing part 82. The sucking/ejecting part 81 sucks gas from its upper surface and ejects gas onto the substrate 16. As gas ejected from the sucking/ejecting part 81 is blown onto the lower surface of the substrate 16, the substrate 16 is levitated. The sucking/ejecting part 81 sucks gas present between the substrate 16 and the sucking/ejecting part 81.

The sucking/ejecting part 81 serves as a precision levitation unit cell formed of a element such as ceramic. As the porous element, porous carbon, porous alumina ceramic, porous SiC ceramic, or the like may be used.

The sucking/ejecting part 81 ejects gas upward. Further, sucking holes for sucking gas are formed in the sucking/ejecting part 81. In the porous element, sucking holes extending to its upper surface are formed, e.g., machined, at predetermined intervals. The sucking holes are minute holes and form a negative pressure between the substrate 16 and the sucking/ejecting part 81. Further, gas is ejected from almost the entire surface of the porous element except for the sucking holes. An ejecting surface for forming a positive pressure is formed in almost the entire surface except for the sucking holes. Alternatively, the sucking/ejecting part 81 may be formed of a metal block with a plurality of sucking holes and a plurality of ejecting holes formed therein.

Since the sucking/ejecting part 81 ejects gas onto the lower surface of the substrate 16, a minute space G is formed between the sucking/ejecting part 81 and the substrate 16. The space G is an air gap formed by gas ejected from the sucking/ejecting part 81. Further, the sucking/ejecting part 81 sucks gas present in the space G. In this way, a sucking force for sucking the substrate 16 downward is generated, so that it is possible to achieve high levitating precision.

A circular window part 83 is formed in the sucking/ejecting part 81. Light from the substrate 16 enters the optical system 51 through the window part 83. The window part 83 may be a space, or a transparent member such as glass may be disposed therein. In this way, the sucking/ejecting part 81 can suck gas in the entire circumference of the observation area on the substrate 16. The sucking/ejecting part 81 can levitate an area surrounding the observation area on the substrate 16 with high levitating precision. The levitating precision of an area around the observation unit 50 can be increased. Therefore, the observation unit 50 can properly take an image of the substrate 16.

Further, this embodiment is configured so that the substrate 16 is not sucked nor fixed. Therefore, the observation unit 50 can take an image of the substrate 16 even during the conveyance of the substrate 16. That is, the observation unit 50 can take an image of the substrate 16 while the substrate 16 is moving. In this way, the observation unit 50 can efficiently take an image of the substrate 16. It is possible to observe and inspect the substrate 16 with high productivity.

### Sixth Embodiment

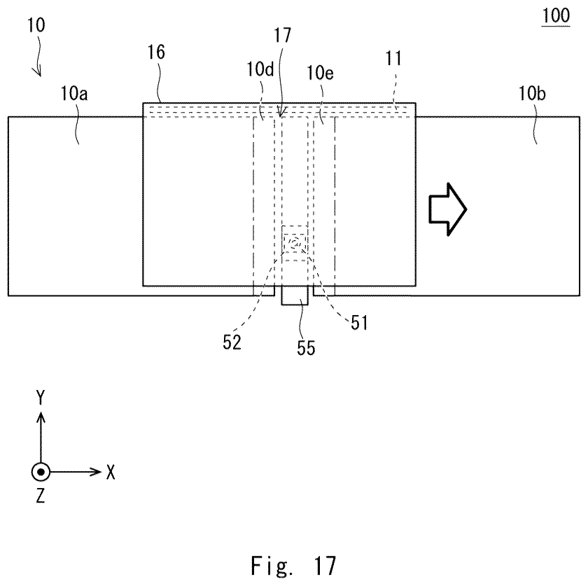

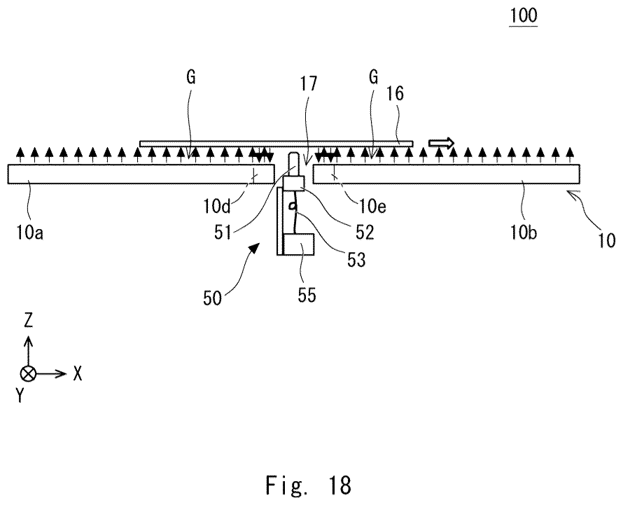

An observation apparatus according to a sixth embodiment will be described with reference to FIGS. 17 and 18. FIG. 17 is an XY plane view showing the configuration of the observation apparatus 100. FIG. 18 is an XZ plane view showing the configuration of the observation apparatus 100.

In this embodiment, the configuration of the levitation unit 10 is different from that in the first embodiment. Specifically, the levitation unit 10 includes levitation unit cells 10a and 10b and precision levitation unit cells 10d and 10e. The rest of the configuration other than the precision levitation unit cells 10d and 10e is similar to that of the first embodiment, and therefore description thereof is omitted.

Similarly to the sucking/ejecting part 81 of the fifth embodiment, each of the precision levitation unit cells 10d and 10e sucks and ejects gas. Since the precision levitation unit cells 10d and 10e eject gas onto the lower surface of the substrate 16, a minute space G is formed between the precision levitation unit cells 10d and 10e and the substrate 16. The space G is an air gap formed by gas ejected from the precision levitation unit cells 10d and 10e. Further, the precision levitation unit cells 10d and 10e suck gas present in the space G. In this way, a sucking force for sucking the substrate 16 downward is generated, so that it is possible to achieve high levitating precision.

In the X direction, the precision levitation unit cells 10d and 10e are disposed on both sides of the observation unit 50. That is, the precision levitation unit cell 10d is disposed on the −X side of the observation unit 50, and the precision levitation unit cell 10e is disposed on the +X side of the observation unit 50. The levitating precision of an area around the observation unit 50 can be increased on both sides thereof in the conveyance direction. Therefore, the observation unit 50 can properly take an image of the substrate 16.

### Seventh Embodiment

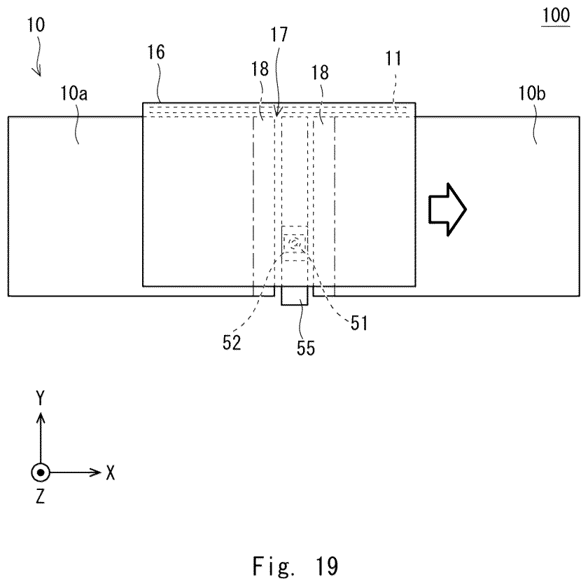

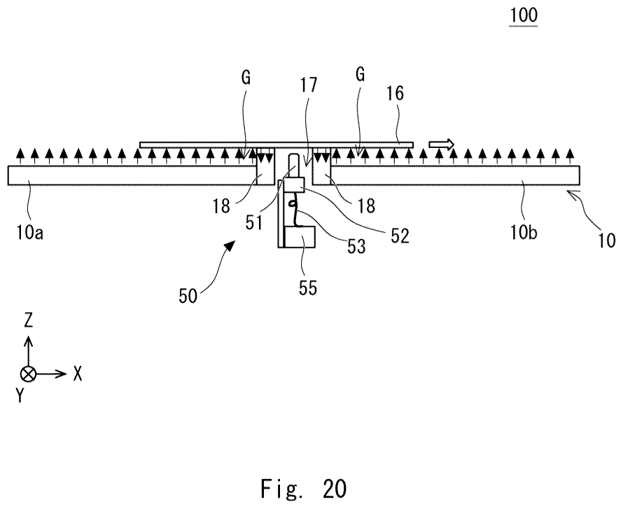

An observation apparatus according to a seventh embodiment will be described with reference to FIGS. 19 and 20. FIG. 19 is an XY plane view showing the configuration of the observation apparatus 100. FIG. 20 is an XZ plane view showing the configuration of the observation apparatus 100.

In this embodiment, sucking units 18 are added to the configuration of the first embodiment. Specifically, the precision levitation unit cells 10d and 10e in the sixth embodiment are replaced by the sucking units 18.

The upper surfaces of the sucking units 18 are higher than the upper surface of the levitation unit 10. The sucking units 18 are disposed on both sides of the observation unit 50 in the conveyance direction. Similarly to the sucking part 61, the sucking units 18 vacuum-suck the substrate 16. That is, the sucking units 18 suck gas present in the space G formed directly below the substrate 16. In this way, the substrate 16 is sucked and fixed to the upper surfaces of the sucking units 18. Fluctuations in the height of the substrate 16 can be suppressed. That is, the observation unit 50 can take an image of the substrate 16 positioned at a fixed height. Therefore, it is possible to observe the substrate 16 in a stable manner.

### Eighth Embodiment

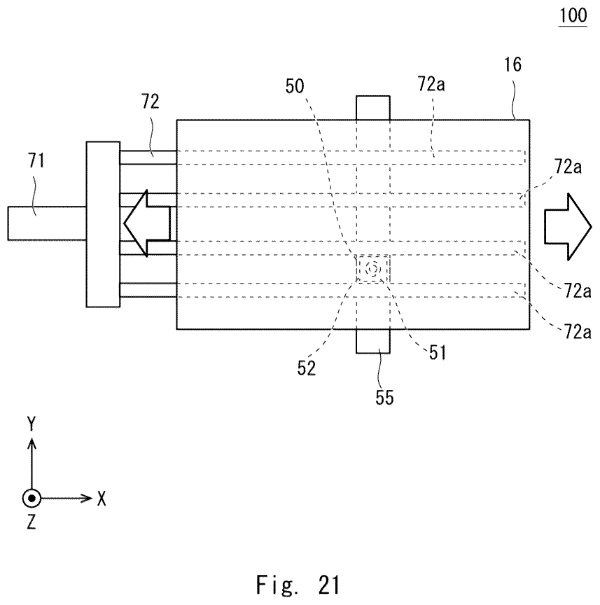

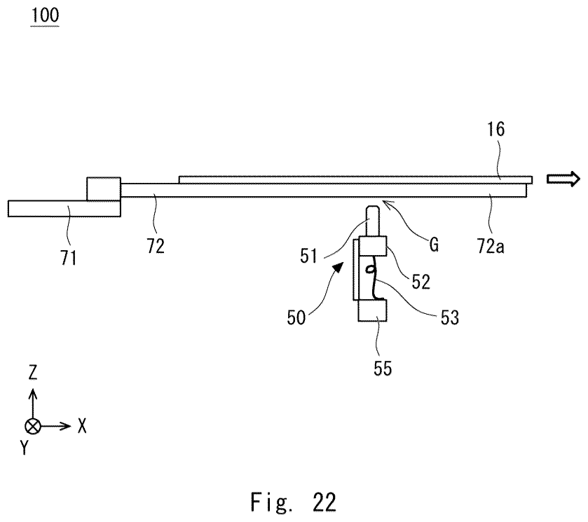

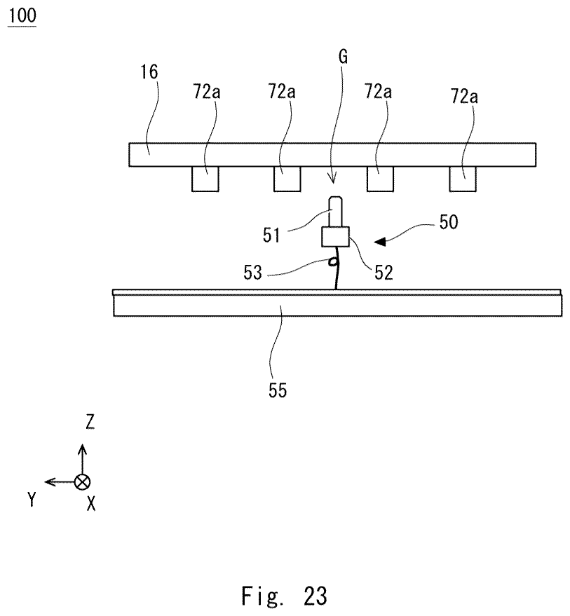

An observation apparatus according to an eighth embodiment will be described with reference to FIGS. 21, 22 and 23. FIG. 21 is an XY plane view showing the configuration of the observation apparatus 100. FIG. 22 is an XZ plane view showing the configuration of the observation apparatus 100. FIG. 23 is a YZ plane view showing the configuration of the observation apparatus 100. Note that the descriptions of matters which are the same as those in the above-described embodiments will be omitted as appropriate. For example, the configuration of the observation unit 50 and the moving mechanism 55 is similar to that in the first embodiment.

In this embodiment, a conveyance robot 70 is provided in place of the levitation unit 10. The conveyance robot 70 includes an arm mechanism 71 and a robot hand 72.

The robot hand 72 is a mechanism for supporting the substrate 16 so that a space G is formed directly below the substrate 16. Specifically, the robot hand 72 includes a fork 72a. The fork 72a extends along the X direction. The substrate 16 is placed over the fork 72a. Spaces G are formed between adjacent prongs of the fork 72a directly below the substrate 16. Note that the robot hand 72 may suck and hold the substrate 16 by vacuum-sucking or the like.

The arm mechanism 71 includes an actuator such as a servomotor and drives the robot hand 72. In this way, as shown in FIG. 22, the substrate 16 is conveyed in the X direction. Further, the moving mechanism 55 moves the observation unit 50 in the Y direction. In this way, it is possible to observe an arbitrary position on the substrate 16.

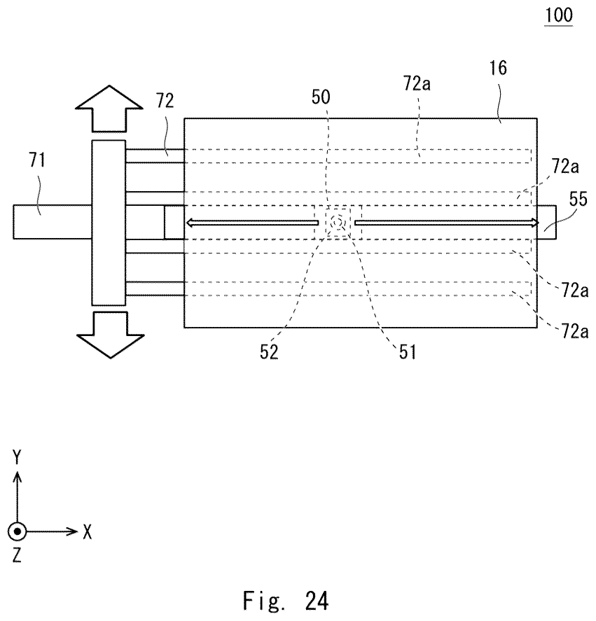

As shown in FIG. 24, the moving directions of the arm mechanism 71 and the moving mechanism 55 may be the other way around. In FIG. 24, the arm mechanism 71 may move the substrate 16 in the Y direction and the moving mechanism 55 may move the substrate 16 in the X direction. As described above, the conveyance direction of the substrate 16 and the moving direction of the observation unit 50 are not limited to any particular directions.

### Ninth Embodiment

Note that although the moving mechanism 55 moves the observation unit 50 in order to change the observation position on the substrate in the first to eighth embodiments, the moving mechanism may move the substrate 16 instead of or in addition to moving the observation unit 50. It is sufficient if the moving mechanism can move the relative position of the observation unit relative to the substrate in a direction inclined from the conveyance direction of the substrate in a plan view. In this embodiment, the moving mechanism moves the substrate 16 disposed over the levitation unit 10 in the Y direction.

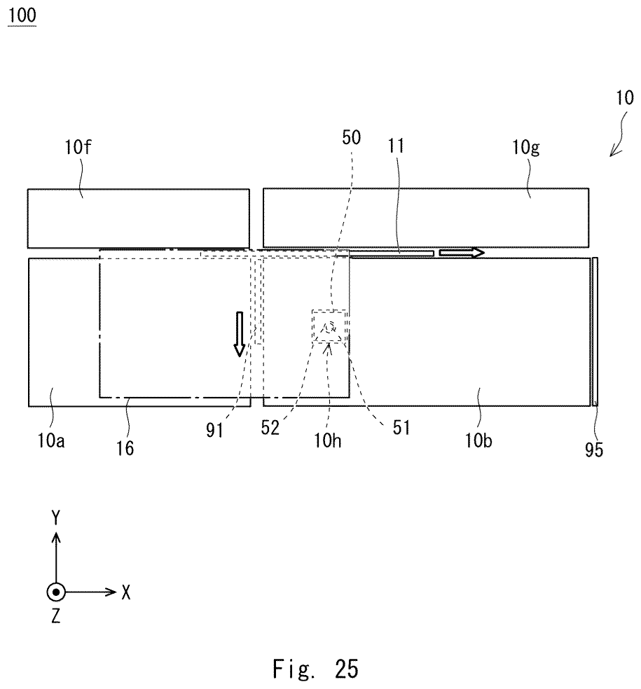

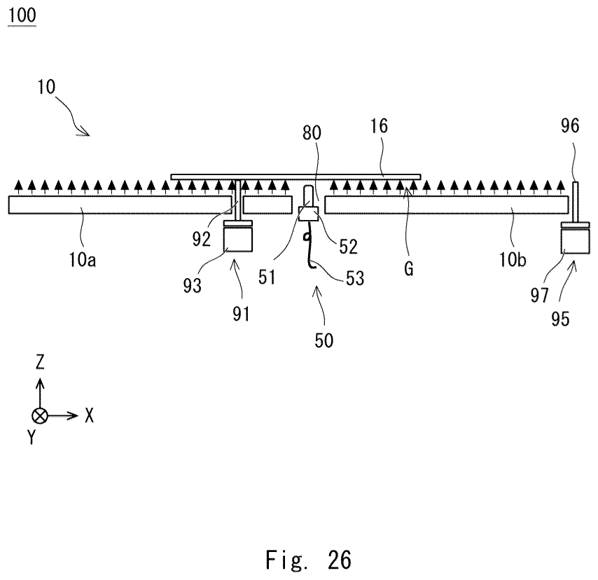

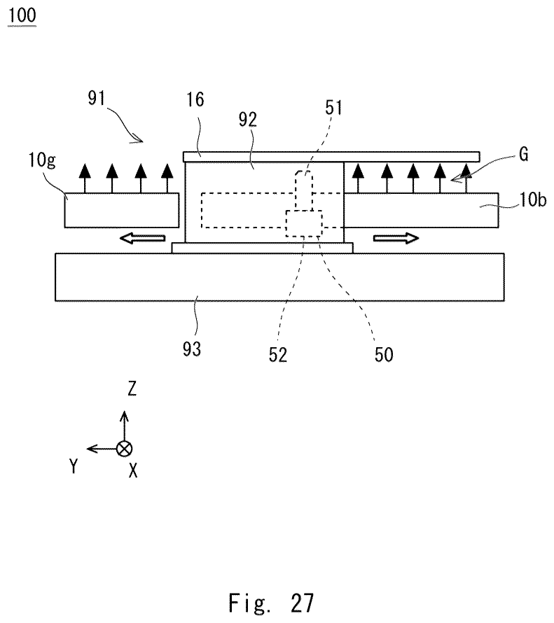

A configuration of an observation apparatus 100 according to this embodiment will be described with reference to FIGS. 25 to 27. FIG. 25 is an XY plane view showing the configuration of the observation apparatus 100. FIG. 26 is an XZ plane view showing the configuration of the observation apparatus 100. FIG. 27 is a YZ plane view showing the configuration of the observation apparatus 100.

In this embodiment, a moving mechanism 91 is provided in place of the moving mechanism 55. The moving mechanism 91 moves the substrate 16 in the Y direction. Therefore, the observation position on the substrate 16 observed by the observation unit 50 changes in the Y direction. The position of the observation unit 50 is fixed. For example, the observation unit 50 is fixed inside an opening 10h formed in the levitation unit cell 10b. Therefore, the observation unit 50 does not move.

More specifically, as shown in FIG. 25, the levitation unit 10 includes levitation unit cells 10a, 10b, 10f and 10g. For example, levitation unit cells 10f and 10g are added to the configuration of the levitation unit 10 shown in FIG. 1. Similarly to the levitation unit cells 10a and 10b, the levitation unit cells 10f and 10g eject gas upward. The levitation unit cell 10f is disposed on the +Y side of the levitation unit cell 10a. The levitation unit cell 10g is disposed on the +Y side of the levitation unit cell 10b.

The conveyance mechanism 11 moves a space formed between the levitation unit cells 10a and 10f in the X direction. The conveyance mechanism 11 moves a space formed between the levitation unit cells 10b and 10g in the X direction. The moving mechanism 91 moves a space formed between the levitation unit cells 10a and 10b in the Y direction. The moving mechanism 91 moves a space formed between the levitation unit cells 10f and 10g in the Y direction.

The moving mechanism 91 has a configuration similar to that of the conveyance mechanism 11, but its conveyance direction is different from that of the conveyance mechanism 11. Specifically, as shown in FIGS. 26 and 27, the moving mechanism 91 includes a holding mechanism 92 and a driving mechanism 93. Similarly to the holding mechanism 12, the holding mechanism 92 sucks and holds the substrate 16. The driving mechanism 93 moves the holding mechanism 92 in the Y direction. Therefore, the moving mechanism 91 can move the substrate 16 in the Y direction. The observation unit 50 is disposed directly below the substrate 16. In this way, the observation position on the substrate 16 can be changed.

Assume that, for example, the conveyance mechanism 11 and the moving mechanism 91 are disposed directly below the substrate 16. In this state, the conveyance mechanism 11 and the moving mechanism 91 can pass the substrate 16 to each other. The holding mechanism 12 releases the holding of the substrate 16 in the state where the holding mechanism 92 holds the substrate 16. As a result, the substrate 16 is passed from the conveyance mechanism 11 to the moving mechanism 91, so that the substrate 16 can be moved in the Y direction. After the substrate 16 is passed from the conveyance mechanism to the moving mechanism, the conveyance mechanism 11 may lower the holding mechanism 12 in order to prevent the holding mechanism 12 from colliding with the substrate 16.

Then, when the driving mechanism 93 drives the holding mechanism 92, the substrate 16 moves in the Y direction. As a result, the observation position on the substrate 16 observed by the observation unit 50 moves in the Y direction. That is, the moving mechanism 91 moves the relative position of the observation unit 50 relative to the substrate 16 in the Y direction.

The holding mechanism 92 releases the holding of the substrate 16 in the state where the holding mechanism 12 holds the substrate 16. As a result, the substrate 16 is passed from the moving mechanism 91 to the conveyance mechanism 11, so that the substrate 16 can be moved in the X direction. After the substrate 16 is passed from the conveyance mechanism to the moving mechanism, the moving mechanism 91 may lower the holding mechanism 92 in order to prevent the holding mechanism 92 from colliding with the substrate 16.

Then, when the driving mechanism 13 drives the holding mechanism 12, the substrate 16 moves in the X direction. As a result, the observation position on the substrate 16 observed by the observation unit 50 moves in the X direction. That is, the conveyance mechanism 11 moves the relative position of the observation unit 50 relative to the substrate 16 in the X direction.

In this embodiment, the substrate 16, instead of the observation unit 50, is moved in the Y direction. By combining the conveyance of the substrate in the X direction by the conveyance mechanism 11 with the conveyance of the substrate in the Y direction by the moving mechanism 91, the observation position observed by the observation unit 50 can be changed in the X and Y directions. Therefore, since the substrate 16 is conveyed in the X and Y directions, the observation apparatus 100 can observe an arbitrary position on the substrate 16.

Further, as shown in FIGS. 25 and 26, a moving mechanism 95 is disposed on the +X side of the levitation unit cell 10b. The moving mechanism 95 has a configuration similar to that of the moving mechanism 91. Specifically, the moving mechanism 95 includes a holding mechanism 96 and a driving mechanism 97. The holding mechanism 96 corresponds to the holding mechanism 92, and the driving mechanism 97 corresponds to the driving mechanism 93. The moving mechanism 95 moves the substrate 16 in the Y direction. For example, after the moving mechanism 91 moves the substrate 16 in the −Y direction, the moving mechanism 95 moves the substrate 16 in the +Y direction. As a result, the substrate 16 returns to its original position in the Y direction.

Further, in this embodiment, a plurality of cells of the precision levitation unit 80 may also be arranged around the observation unit 50. Alternatively, a sucking unit(s) 60 may be disposed around the observation unit 50.

### Tenth Embodiment

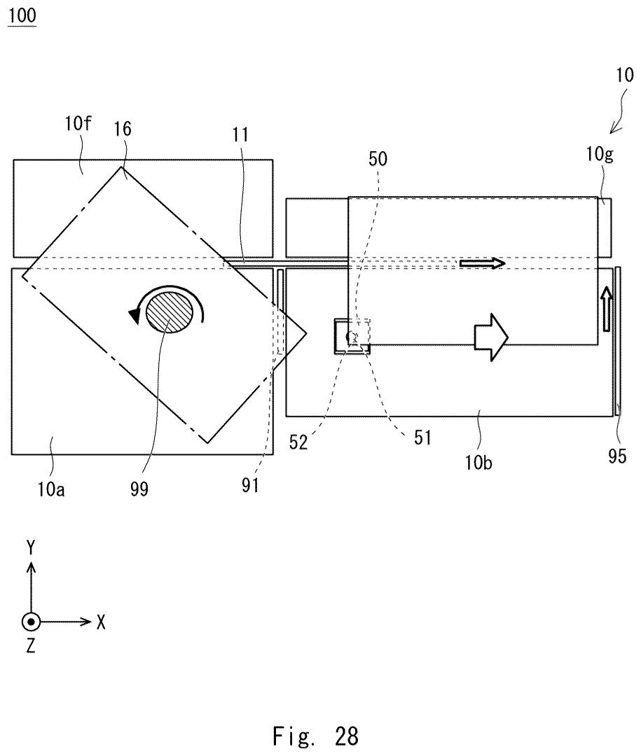

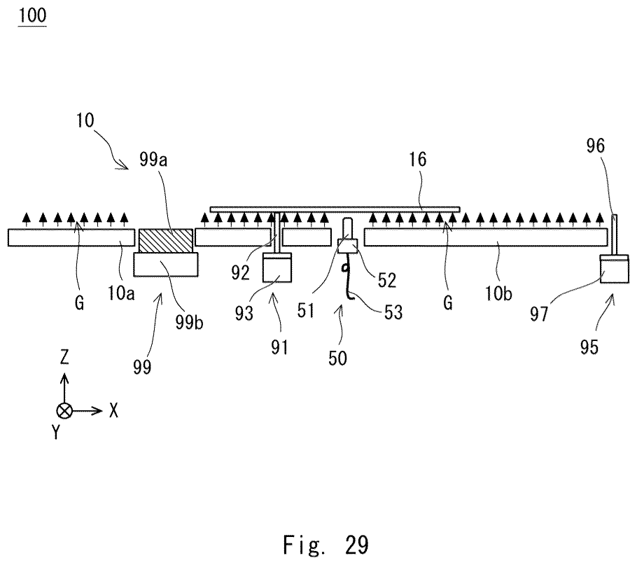

A configuration of an observation apparatus 100 according to a tenth embodiment will be described with reference to FIGS. 28 and 29. In this embodiment, a rotating mechanism 99 is added to the configuration of the ninth embodiment. The rest of the configuration other than the rotating mechanism 99 is similar to those of the above-described embodiments, and therefore description thereof is omitted.

The rotating mechanism 99 rotates the substrate 16 levitating over the levitation unit 10 around the Z-axis. The rotating mechanism 99 is disposed in an opening formed in the levitation unit cell 10a. The rotating mechanism 99 includes a holding mechanism 99a and a driving mechanism 99b. Similarly to the holding mechanisms 12 and 92 and the like, the holding mechanism 99a sucks and holds the substrate 16. The driving mechanism 99b includes a motor and a rotation shaft for rotating the holding mechanism 99a. The rotation shaft is parallel to the Z direction.

The holding mechanism 99a holds the substrate 16 in a state where the levitation unit cells 10a and 10f and the like eject gas onto the substrate 16. Then, as the driving mechanism 99b rotates the holding mechanism 99a, the substrate 16 rotates around the Z axis. For example, the rotating mechanism 99 rotates the substrate 16 by 90° or 180° around the Z axis. It is possible to change the observation position on the substrate 16 by using the rotating mechanism 99. As described above, in this embodiment, the observation apparatus 100 can move the substrate 16 with three degrees of freedom, i.e., along the X axis, along the Y axis, and around the rotation axis. Therefore, the observation apparatus 100 can observe the entire surface of the substrate 16.

As described above, the observation apparatus 100 includes: a mechanism for levitating or supporting a substrate so that a space is formed directly below the substrate; and an observation unit including a photodetector configured to detect light from the substrate, and an optical system configured to guide the light from the substrate to the photodetector. Further, an observation method performed in the observation apparatus includes the following steps (A1) to (A3).
(A1) A step in which a conveyance mechanism conveys the substrate in a conveyance direction.
(A2) A step of observing the substrate conveyed by the conveyance mechanism by using the observation unit.
(A3) A step of observing the substrate while changing an observation position on the substrate by moving the relative position of the observation unit relative to the substrate in a direction inclined from the conveyance direction in a plan view.

The configurations of the first to tenth embodiments can be used while combining them with one another as appropriate. Further, each of the observation apparatuses 100 shown in the first to tenth embodiments can be applied to an apparatus for manufacturing a semiconductor device. It is possible to properly observe a substrate in a process for manufacturing a semiconductor device. Therefore, a semiconductor device can be manufactured with high productivity.

For example, the observation apparatus 100 may be provided in a part of a laser irradiation apparatus. FIG. 25 is an XZ cross-sectional view showing a configuration of a laser irradiation apparatus 1 including an observation apparatus 100 according to the first embodiment. The laser irradiation apparatus 1 is, for example, an excimer laser annealing (ELA: Excimer laser Anneal) apparatus for forming a low-temperature poly-silicon (LTPS: Low Temperature Poly Silicon) film. In this case, the substrate 16 is a glass substrate over which an amorphous silicon film is formed.

The laser irradiation apparatus 1 includes the observation apparatus 100 and a laser irradiation unit 14. In this example, the laser irradiation apparatus 1 has a configuration that is obtained by adding the laser irradiation unit 14 in the observation apparatus 100 shown in FIG. 1. The laser irradiation unit 14 is disposed above the substrate 16 during the conveyance thereof in the X direction. In FIG. 25, the laser irradiation unit 14 is disposed above the levitation unit cell 10b.

The laser irradiation unit 14 includes a laser light source for generating laser light 15 and an illumination optical system for guiding the laser light 15 to the substrate 16. The laser irradiation unit 14 applies a line beam (i.e., a light beam of which the irradiated area has a linear shape) of which the longitudinal direction is parallel to the Y direction to the substrate 16. Since the substrate 16 is conveyed in the X direction, it is possible to irradiate almost the entire surface of the substrate 16 with laser light.

For example, the laser irradiation unit 14 includes an excimer laser light source for generating laser light. Further, the laser irradiation unit 14 includes an optical system for guiding the laser light to the substrate 16. The laser irradiation unit 14 includes a lens for concentrating the laser light 15 on the substrate 16. For example, the laser irradiation unit 14 includes a cylindrical lens for forming a linear irradiated area. The substrate 16 is irradiated with a line-shaped laser light 15 (line beam, i.e., a light beam of which the irradiated area has a linear shape), in particular, laser light 15 of which the focal point extends in the y direction. The focal point of the laser light 15 is formed on the substrate 16.

The levitation unit 10 levitates the substrate 16 with high precision. Therefore, the laser irradiation unit 14 can properly apply the laser light to the substrate 16. Since the in-plane variations of the laser light can be suppressed, a uniform process can be performed. The levitating height can be made uniform. Therefore, a more stable process can be performed, so that a uniform polysilicon film can be formed. Therefore, the productivity can be improved.

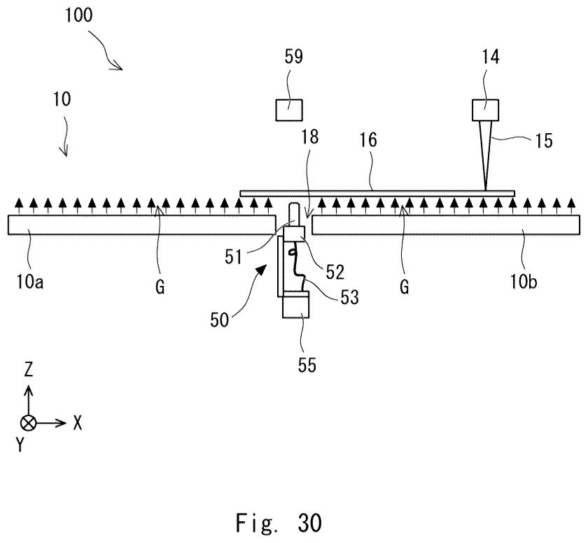

In FIG. 30, the substrate 16 which has already been irradiated with laser light can be observed. Needless to say, the substrate 16 which has not yet been irradiated with laser light may also be observed. In this case, the laser irradiation unit 14 may apply laser light to the substrate on the −X side of the observation unit 50. For example, the laser irradiation unit 14 may be disposed above the levitation unit cell 10a.

Note that although the example in which the observation apparatus 100 is applied to the laser irradiation apparatus 1 has been described above with reference to FIG. 30, the observation apparatus 100 can be applied to apparatuses other than the laser irradiation apparatus. That is, it is possible to apply the observation apparatus 100 to manufacturing apparatuses used in the manufacturing process of semiconductor devices.

### Organic EL Display

A semiconductor device having the above-described polysilicon film is suitable for a TFT (Thin Film transistor) array substrate for an organic EL (ElectroLuminescence) display. That is, the polysilicon film is used as a semiconductor layer including source regions, channel regions, and drain regions of TFTs.

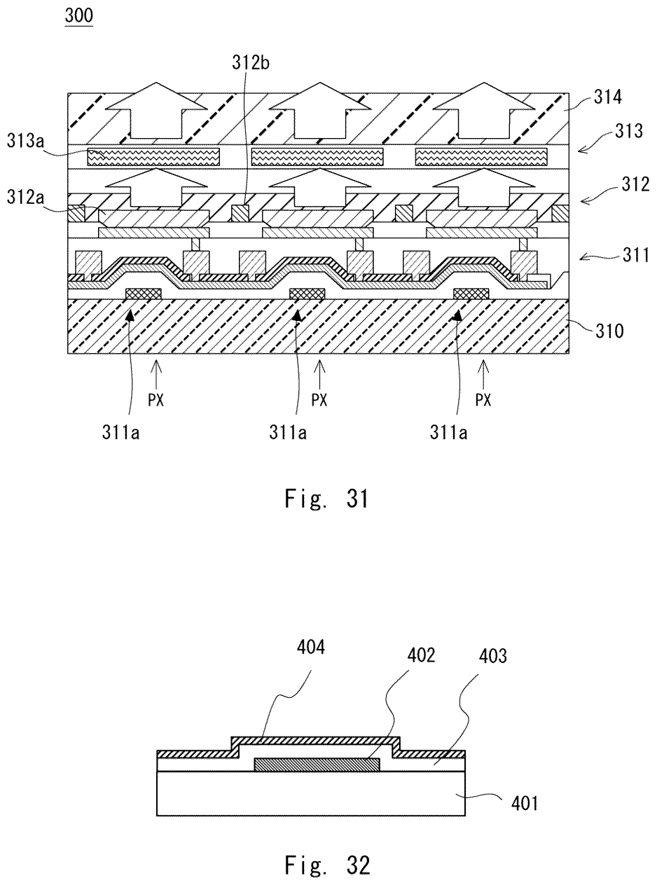

A configuration in which a semiconductor device according to this embodiment is applied to an organic EL display will be described hereinafter. FIG. 31 is a simplified cross-sectional view of pixel circuits of an organic EL display device. The organic EL display 300 shown in FIG. 31 is an active matrix-type display device in which a TFT(s) is disposed in each pixel PX.

The organic EL display device 300 includes a substrate 310, a TFT layer 311, an organic layer 312, a color filter layer 313, and a sealing substrate 314. FIG. 31 shows a top-emission-type organic EL display device, in which the side of the sealing substrate 314 is located on the viewing side. Note that the following description is given to show an example of a configuration of an organic EL display device and this embodiment is not limited to the below-described configuration. For example, a semiconductor device according to this embodiment may be used for a bottom-emission-type organic EL display device.

The substrate 310 is a glass substrate or a metal substrate. The TFT layer 311 is provided over the substrate 310. The TFT layer 311 includes TFTs 311a disposed in the respective pixels PX. Further, the TFT layer 311 includes wiring lines (not shown) or the like connected to the TFTs 311a. The TFTs 311a, the wirings, and the like constitute pixel circuits.

The organic layer 312 is provided over the TFT layer 311. The organic layer 312 includes an organic EL light-emitting element 312a disposed in each pixel PX. Further, in the organic layer 312, separation walls 312b for separating organic EL light-emitting elements 312a are provided between pixels PX.

The color filter layer 313 is provided over the organic layer 312. The color filter layer 313 includes color filters 313a for performing color displaying. That is, in each pixel PX, a resin layer colored in R (red), G (green), or B (blue) is provided as the color filter 313a.

The sealing substrate 314 is provided over the color filter layer 313. The sealing substrate 314 is a transparent substrate such as a glass substrate and is provided to prevent deterioration of the organic EL light-emitting elements of the organic layer 312.

Electric currents flowing through the organic EL light-emitting elements 312a of the organic layer 312 are changed by display signals supplied to the pixel circuits. Therefore, it is possible to control an amount of light emitted in each pixel PX by supplying a display signal corresponding to a display image to each pixel PX. As a result, it is possible to display a desired image.

In an active matrix-type display device such as an organic EL display, at least one TFT (e.g., a switching TFT or a driving TFT) is provided in one pixel PX. Further, a semiconductor layer including a source region, a channel region, and a drain region is provided in the TFT in each pixel PX. A polysilicon film according to this embodiment is suitable for a semiconductor layer of TFTs. That is, by using a polysilicon film manufactured by the above-described manufacturing method for a semiconductor layer of a TFT array substrate, it is possible to prevent or reduce in plane variations of TFT characteristics. Therefore, it is possible to manufacture display devices having excellent display characteristics with high productivity.

### Method for Manufacturing Semiconductor Device

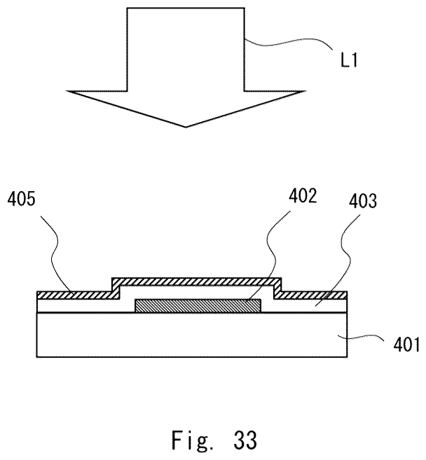

The method for manufacturing a semiconductor device by using a laser irradiation apparatus according to this embodiment is suitable for manufacturing of a TFT array substrate. A method for manufacturing a semiconductor device including a TFT will be described with reference to FIGS. 26 and 32. Each of FIGS. 32 and 33 is a cross-sectional view showing a step in a method for manufacturing a semiconductor device. In the following description, a method for manufacturing a semiconductor device including an inverted staggered-type TFT will be described. Each of FIGS. 32 and 33 shows one of the steps for forming a polysilicon film in a method for manufacturing a semiconductor. Note that other manufacturing steps can be performed by using known techniques, and therefore descriptions thereof are omitted as appropriate.

As shown in FIG. 32, a gate electrode 402 is formed over a glass substrate 401. A gate insulating film 403 is formed over the gate electrode 402. An amorphous silicon film 404 is formed over the gate insulating film 403. The amorphous silicon film 404 is disposed so as to be placed over the gate electrode 402 with the gate insulating film 403 interposed therebetween. For example, the gate insulating film 403 and the amorphous silicon film 404 are successively formed by a CVD (Chemical Vapor Deposition) method.

Then, the glass substrate 401, on which the amorphous silicon film 404 has been formed, is conveyed to the above-described conveyance apparatus 600. By irradiating the amorphous silicon film 404 with laser light L1, a polysilicon film 405 is formed as shown in FIG. 33. That is, the amorphous silicon film 404 is crystallized by the laser irradiation apparatus 1 shown in FIG. 25 or the like. As a result, a polysilicon film 405 that is formed as silicon is crystallized is formed over the gate insulating film 403. The polysilicon film 405 corresponds to the above-described polysilicon film. The glass substrate 401 is irradiated with the laser light L1 while the conveyance apparatus 600 is conveying the glass substrate 401. As a result, the amorphous silicon film 404 is annealed and converted into a polysilicon film 405.

Further, the above descriptions are given on the assumption that a laser annealing apparatus according to this embodiment is one in which a polysilicon film is formed by applying laser light to an amorphous silicon film. However, the present disclosure may be applied to other cases in which a micro-crystalline film is formed by applying laser light to an amorphous silicon film. Further, the laser light used for the annealing is not limited to Nd: YAG laser. Further, a method according to this embodiment can also be applied to a laser annealing apparatus for crystallizing a thin film other than the silicon film. That is, the method according to this embodiment can be applied to any laser annealing apparatus in which a crystallized film is formed by applying laser light to an amorphous film. According to the laser annealing apparatus in accordance with this embodiment, it is possible to properly reform (or modify) a substrate including a crystallized film.

A method for manufacturing a semiconductor device according to this embodiment may include the following steps (S1) to (S4).
(S1) A step of levitating or supporting a substrate by using a mechanism so that a space is formed directly below the substrate.
(S2) A step of conveying the substrate levitated or supported above the mechanism in a conveyance direction by using a conveyance mechanism.
(S3) A step of observing the substrate by using an observation unit including a photodetector configured to detect light from the substrate, and an optical system configured to guide the light from the substrate to the photodetector.
(S4) A step of moving a relative position of the observation unit relative to the substrate in a direction inclined from the conveyance direction in a plan view by using a moving mechanism so as to change an observation position on the substrate.

Further, the conveyance mechanism may convey the substrate so that the laser irradiation unit applies laser light to the substrate before or after the observation by the observation unit.

Note that the present invention is not limited to the above-described embodiments, and they can be modified as appropriate without departing from the scope and spirit of the invention.

### REFERENCE SIGNS LIST

10 LEVITATION UNIT
11 CONVEYANCE MECHANISM
12 HOLDING MECHANISM
13 DRIVING MECHANISM
16 SUBSTRATE
30 SUPPORT UNIT
31 BASE STAGE
33 CONVEYANCE ROLLER
50 OBSERVATION UNIT
51 OPTICAL SYSTEM
51a OBJECTIVE LENS
52 PHOTODETECTOR
53 CABLE
55 MOVING MECHANISM
59 ILLUMINATION LIGHT SOURCE
60 SUCKING UNIT
61 SUCKING PART
62 STORAGE PART
63 WINDOW PART
70 CONVEYANCE ROBOT
71 ARM MECHANISM
72a ROBOT HAND
72a FORK
80 PRECISION LEVITATION UNIT
81 SUCTION/EJECTION PART
82 STORAGE PART
83 WINDOW PART
100 OBSERVATION APPARATUS

1. An observation apparatus comprising:
a mechanism configured to levitate or support a substrate so that a space is formed directly below the substrate;
a conveyance mechanism configured to convey the substrate levitated or supported above the mechanism in a conveyance direction;
an observation unit comprising a photodetector configured to detect light from the substrate, and an optical system configured to guide the light from the substrate to the photodetector; and
a moving mechanism configured to move a relative position of the observation unit relative to the substrate in a direction inclined from the conveyance direction in a plan view so as to change an observation position on the substrate.

2. The observation apparatus according to claim 1, wherein
the mechanism comprises a levitation unit configured to eject gas onto the substrate, and
parts of the levitation unit are disposed on both sides of the observation unit in the conveyance direction.

3. The observation apparatus according to claim 2, wherein the moving mechanism moves the observation unit.

4. The observation apparatus according to claim 2, wherein the moving mechanism moves the substrate.

5. The observation apparatus according to claim 2, further comprising a sucking unit configured to vacuum-suck the substrate in a vicinity of the observation unit, wherein
the observation unit observes the substrate in a state where the sucking unit sucks and fixes the substrate.

6. The observation apparatus according to claim 2, wherein the observation unit observes the substrate in a state where gas is ejected onto a lower surface of the substrate and gas present below the substrate is sucked in a vicinity of the observation unit.

7. The observation apparatus according to claim 1, wherein the mechanism comprises a plurality of conveyance rollers configured to support the substrate, and
the plurality of conveyance rollers rotate so that the substrate is conveyed in the conveyance direction.

8. The observation apparatus according to claim 1, wherein
the mechanism comprises a robot hand configured to support the substrate, and
the conveyance mechanism comprises an arm mechanism configured to drive the robot hand.

9. An observation method performed in an observation apparatus,
the observation apparatus comprising:
a mechanism configured to levitate or support a substrate so that a space is formed directly below the substrate; and
an observation unit comprising a photodetector configured to detect light from the substrate, and an optical system configured to guide the light from the substrate to the photodetector,
the observation method comprising: steps of
(A1) conveying the substrate in a conveyance direction by using a conveyance mechanism;
(A2) observing the substrate conveyed by the conveyance mechanism by using the observation unit; and
(A3) observing the substrate while changing an observation position on the substrate by moving a relative position of the observation unit relative to the substrate in a direction inclined from the conveyance direction in a plan view.

10. The observation method according to claim 9, wherein
the mechanism comprises a levitation unit configured to eject gas onto the substrate, and
parts of the levitation unit are disposed on both sides of the observation unit in the conveyance direction.

11. The observation method according to claim 10, wherein in the step (A3), the observation unit is moved.

12. The observation method according to claim 10, wherein in the step (A3), the substrate is moved.

13. The observation method according to claim 10, wherein
the observation apparatus further comprises a sucking unit configured to vacuum-suck the substrate in a vicinity of the observation unit, and
the observation unit observes the substrate in a state where the sucking unit sucks and fixes the substrate.

14. The observation method according to claim 10, wherein the observation unit observes the substrate in a state where gas is ejected onto a lower surface of the substrate and gas present below the substrate is sucked in a vicinity of the observation unit.

15. The observation method according to claim 9, wherein
the mechanism comprises a plurality of conveyance rollers configured to support the substrate, and
the plurality of conveyance rollers rotate so that the substrate is conveyed in the conveyance direction.

16. The observation method according to claim 9, wherein
the mechanism comprises a robot hand configured to support the substrate, and
the conveyance mechanism comprises an arm mechanism configured to drive the robot hand.

17. A method for manufacturing a semiconductor device, comprising:
(S1) a step of levitating or supporting a substrate by using a mechanism so that a space is formed directly below the substrate;
(S2) a step of conveying the substrate levitated or supported above the mechanism in a conveyance direction by using a conveyance mechanism;
(S3) a step of observing the substrate by using an observation unit comprising a photodetector configured to detect light from the substrate, and an optical system configured to guide the light from the substrate to the photodetector; and
(S4) a step of moving a relative position of the observation unit relative to the substrate in a direction inclined from the conveyance direction in a plan view by using a moving mechanism so as to change an observation position on the substrate.

18. The method for manufacturing a semiconductor device according to claim 17, wherein
the mechanism comprises a levitation unit configured to eject gas onto the substrate, and
parts of the levitation unit are disposed on both sides of the observation unit in the conveyance direction.

19. The method for manufacturing a semiconductor device according to claim 18, wherein in the step (S4), the moving mechanism moves the observation unit.

20. The method for manufacturing a semiconductor device according to claim 18, wherein in the step (S4), the moving mechanism moves the substrate.

21. to 24. (canceled)
